(19) United States
(12) Patent Application Publication
(10) Pub. No.: US 2014/0293531 A1
(43) Pub. Date: Oct. 2, 2014

(54) SERVER NODE

(71) Applicant: HEWLETT-PACKARD DEVELOPMENT COMPANY, L.P., Houston, TX (US)

(72) Inventors: Robert J. Brooks, Fort Collins, CO (US); Scott Michael Fehringer, Fort Collins, CO (US)

(73) Assignee: Hewlett-Packard Development Company, L.P., Houston, TX (US)

(21) Appl. No.: 13/851,750

(22) Filed: Mar. 27, 2013

(51) Int. Cl. G06F 1/16; H05K 3/00; G06F 1/20

(52) U.S. Cl. CPC G06F 1/16; G06F 1/206; H05K 3/00
USPC 361/679.47; 361/679.02; 361/679.54; 29/832

(57) ABSTRACT

According to an example, a server node may include a base module and a plurality of face modules rotatably coupled to the base module to form an enclosure. The base module and a face module of the plurality of face modules may each include an inner surface that includes an electrical component. A flexible printed circuit interconnect may communicatively interconnect the electrical component on the inner surface of the base module to the electrical component on the inner surface of the face module.

### BACKGROUND

A server typically includes a physical computer or a computer program dedicated to run services to serve the needs of users of other computers on a network, or computer programs that are executed to serve the requests of other programs. Typical examples of servers include database servers, file servers, mail servers, print servers, and web servers. The physical configurations of servers have evolved from large custom boxes to standard-sized enclosures in standard racks, and further to bladed systems. Such trends in the physical server configurations are based, for example, on an attempt to increase the density and efficiency of server components.

### BRIEF DESCRIPTION OF DRAWINGS

Features of the present disclosure are illustrated by way of example and not limited in the following figure(s), in which like numerals indicate like elements, in which:

FIG. 1 illustrates an isometric view of a server node in a fully unfolded configuration, according to an example of the present disclosure;

FIG. 2 illustrates an isometric view of the server node of FIG. 1 in a partially folded configuration, according to an example of the present disclosure;

FIG. 3 illustrates another isometric view of the server node of FIG. 1 in a partially folded configuration, and an associated heat sink in a disassembled configuration, according to an example of the present disclosure;

FIG. 4 illustrates another isometric view of the server node of FIG. 1 in a partially folded configuration, and the associated heat sink in an assembled configuration, according to an example of the present disclosure;

FIG. 5 illustrates an isometric view of the server node of FIG. 1 in a fully folded configuration, and an associated server node connection rod in an assembled configuration, according to an example of the present disclosure;

FIG. 6 illustrates another isometric view of the server node of FIG. 1 in a folded configuration, and an adapter used with the server node, according to an example of the present disclosure;

FIG. 7 illustrates an isometric view of a cluster of server nodes, according to an example of the present disclosure;

FIG. 8 illustrates an isometric view of a cluster of server nodes in a cylindrical configuration, according to an example of the present disclosure;

FIG. 9 illustrates a method for assembling a server node, according to an example of the present disclosure;

FIG. 10 illustrates further details of the method for assembling a server node, according to an example of the present disclosure; and

FIG. 11 illustrates a computer system, according to an example of the present disclosure.

### DETAILED DESCRIPTION

For simplicity and illustrative purposes, the present disclosure is described by referring mainly to examples. In the following description, numerous specific details are set forth in order to provide a thorough understanding of the present disclosure. It will be readily apparent however, that the present disclosure may be practiced without limitation to these specific details. In other instances, some methods and structures have not been described in detail so as not to unnecessarily obscure the present disclosure.

Throughout the present disclosure, the terms “a” and “an” are intended to denote at least one of a particular element. As used herein, the term “includes” means includes but not limited to, the term “including” means including but not limited to. The term “based on” means based at least in part on.

Technological advancements continue to provide improvements in functionality that can be integrated onto a single chip. Such technological advancements have led to higher density packaging needs for such chips and related components. Factors that are considered for packaging designs include the performance needs of devices that use such components. For example, servers that use such chips and related components may include bladed designs that include blade enclosures that hold multiple removable blade servers.

According to an example, a server node is disclosed herein and provides high density packaging for such chips and related components. The server node may include server functionality such as processing, memory, storage, and networking, in a form factor that may be embodied as a cube. According to a specific example, the cube may be approximately two inches on each side. The server node may include a low-power architecture configuration to reduce the average operating power of the server node. A heat sink may be provided to maintain the temperature of the server node and a cluster that includes a plurality of server nodes within predetermined thermal parameters. A peer-to-peer optical mesh interconnect arrangement may provide direct interconnection of server nodes to neighboring server nodes without the use of cables. The server node may thus provide compute density, low latency, and low power consumption, for example, based on the physical locality of memory and other electrical components thereof. The server node may also provide a compact form factor that includes low communication latency between server nodes in a cluster arrangement.

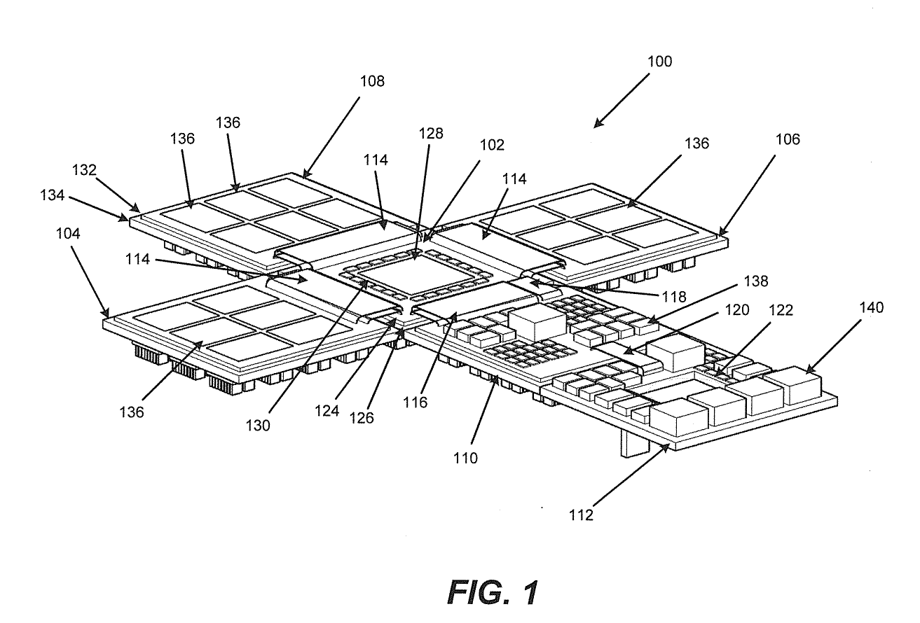

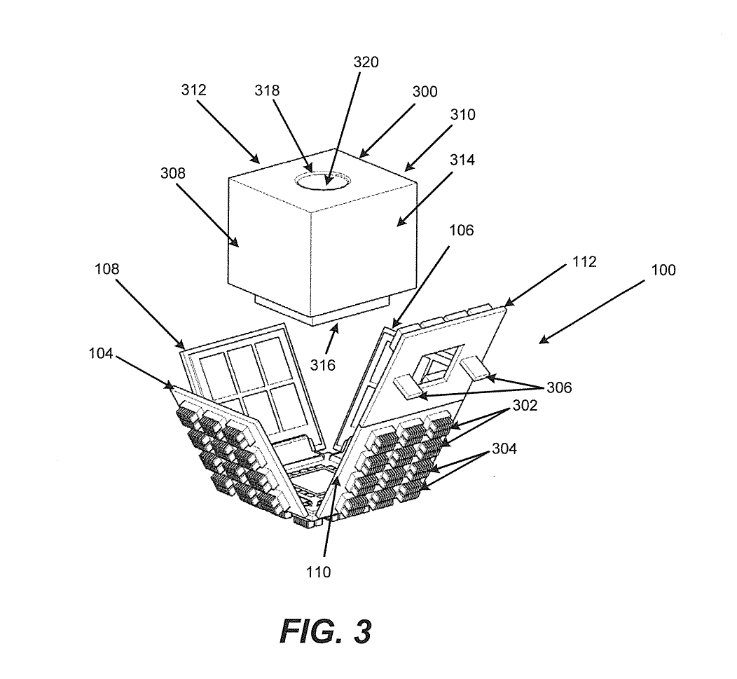

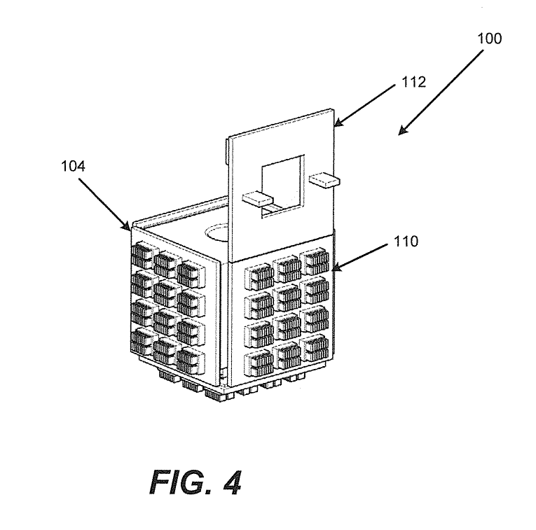

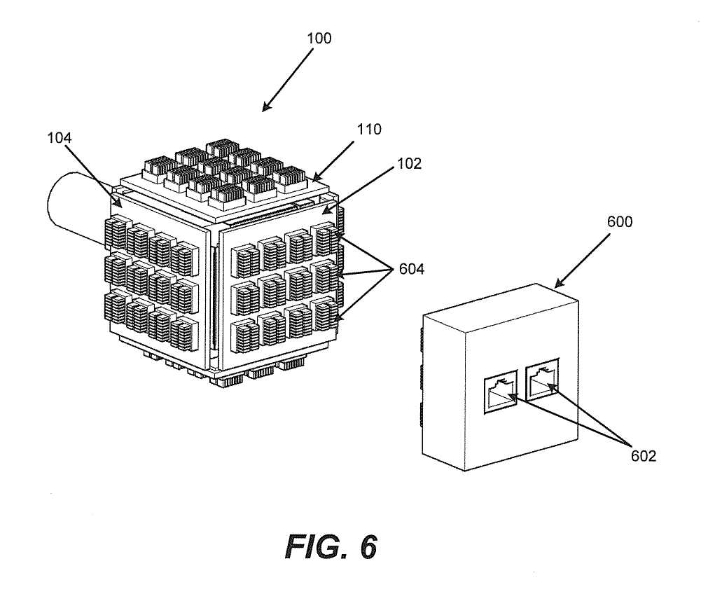

FIG. 1 illustrates an isometric view of a server node 100 in a fully unfolded configuration, according to an example of the present disclosure. FIGS. 3, 4, and 6, which are described in further detail below, illustrate other features of the sever node 100 and related components. For example, FIG. 3 illustrates another isometric view of the server node 100 in a partially folded configuration and an associated heat sink 300 in an unassembled configuration, FIG. 4 illustrates an isometric view of the server node 100 in a partially folded configuration and the associated heat sink 300 in an assembled configuration, and FIG. 6 illustrates an isometric view of the server node 100 in a fully folded configuration and an adapter 600 used with the server node, according to examples of the present disclosure. Referring to FIG. 1, the server node 100 is depicted as including six modules that include a base module 102, face modules 104, 106, 108, and 110, and a head module 112. The modules 102, 104, 106, 108, 110, and 112 may each include a square configuration as shown in FIG. 1. However, those skilled in the art would appreciate in view of this disclosure that the modules 102, 104, 106, 108, 110, and 112 may include other configurations. For example, the face modules 104, 106, 108, and 110 may each include a rectangular configuration. Further, although four face modules 104, 106, 108, and 110 are illustrated, additional face modules may be used to provide, for example, a pentagonal or other configurations.

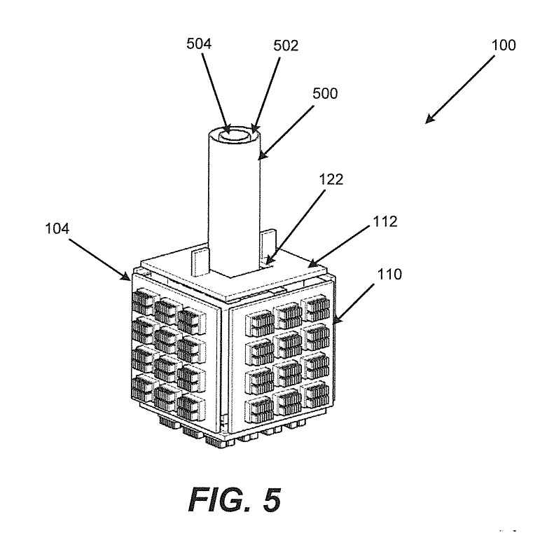

The modules 102, 104, 106, 108, 110, and 112 may be interconnected by flexible printed circuit interconnects. For example, the modules 102, 104, 106, and 108 may be interconnected by flexible printed circuit interconnects 114. Similarly, the modules 102 and 110 may be interconnected by flexible printed circuit interconnects 116 and 118, and the modules 110 and 112 may be interconnected by a flexible printed circuit interconnect 120. The modules 102, 104, 106, 108, 110, and 112 may therefore be rotatably attached to each other via the flexible printed circuit interconnects 114, 116, and 118. In addition, or alternatively, the modules 102, 104, 106, 108, 110, and 112 may also be detachably connected to each other. The modules 102, 104, 106, 108, 110, and 112 may be formed of heat-conducting materials such as copper, aluminum, alloys, etc. Referring to FIGS. 1 and 5, the head module 112 may include an aperture 122 for a server node connection rod 500.

The base module 102 may include a substrate 124 and a printed circuit (PC) board 126. The substrate 124 may be an organic or a ceramic substrate, or another type of substrate. The substrate 124 may alternatively include a silicon (Si) interposer, or may be formed as a multichip-module (MCM) substrate. The base module 102 may include a system on chip (SOC) 128 that integrates all of the components of the server node 100. The SOC 128 may include a processor, memory controller, fabric interface and switch, and onboard management of various components of the server node 100. Alternatively or additionally, the base module 102 may include ancillary chips that add functionality not included on the SOC 128, and decoupling capacitors (e.g., at 130).

The face modules 104, 106, 108, and 110 may similarly include substrates 132 and PC boards 134. Memory 136 or other types of storage may be provided on the face modules 104, 106, and 108. For example, the face modules 104, 106, and 108 may include volatile memory (e.g., dynamic random-access memory (DRAM)), non-volatile memory (e.g., flash), and/or combinations of different types of memory. The face module 110 may include power delivery circuitry 138 for the components of the server node 100 and/or for other adjacently disposed server nodes. The head module 112 may similarly include power delivery circuitry 140 for the components of the server node 100 and/or for other adjacently connected server nodes.

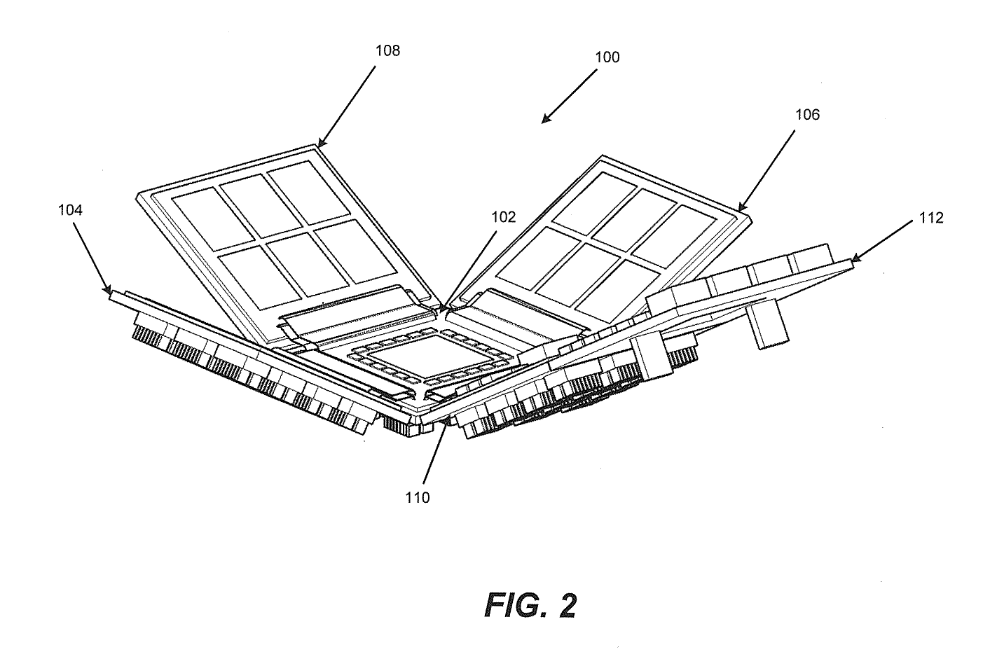

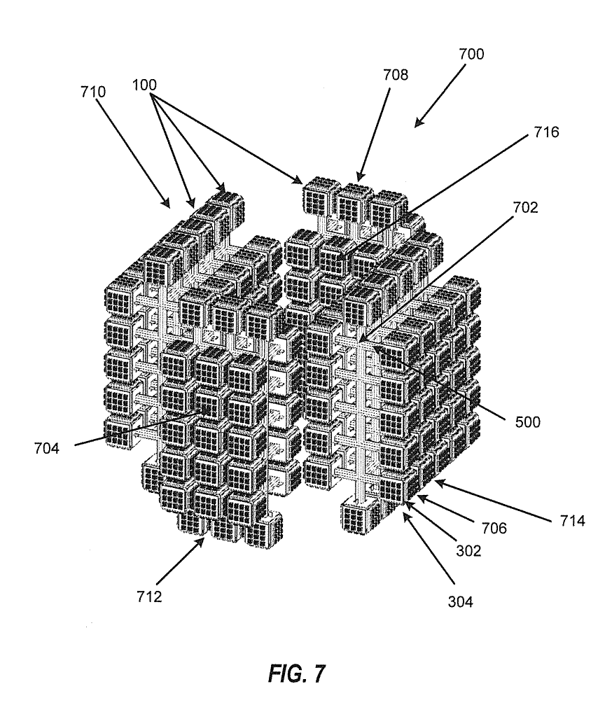

Referring to FIGS. 1-3, the exposed sides of the face modules 104, 106, 108, and 110 (i.e., sides exposed to other adjacently disposed server nodes or adapters) may include optical (or generally electrical) input/output (I/O) receivers and transmitters for communication with other adjacently connected server nodes. For example, as illustrated in FIG. 3, the rows 302 may be designated as input optical receivers and the rows 304 may be designated as output optical transmitters. The exposed side of the head module 112 may include power connectors 306 for supplying power to the power delivery circuitry 138 and 140 of the face module 110 and the head module 112, respectively. The I/O receivers and transmitters on the exposed sides of the face modules 104, 106, 108, and 110 may be used to form a peer-to-peer mesh when connected to I/O receivers and transmitters of other server nodes, for example, as shown in FIG. 7.

Referring to FIGS. 1-3, FIG. 3 further illustrates the associated heat sink 300 in a disassembled configuration, according to an example of the present disclosure. The heat sink 300 may be formed of heat conducting materials such as copper, aluminum, alloys, etc., to dissipate heat during operation of the sever node 100. The heat sink 300 may include surfaces 308, 310 (opposite to surface 308), 312 (opposite to surface 314), and 314. The surfaces 308, 310, 312, and 314 may be contiguously engaged with or disposed a predetermined distance from components such as the memory 136 of the face modules 104, 106, and 108, and power delivery circuitry 138 of the face module 110. Further, the heat sink 300 may include a surface 316 that is contiguously engaged with or disposed a predetermined distance from the SOC 128 of the base module 102. An aperture 318 may provide for a reservoir 320 for receiving cooling fluid (or fluid to maintain the sever node 100 at a predetermined temperature) via the server node connection rod 500 as shown in FIG. 5. The heat sink 300 may include passages therein for facilitating circulation of the cooling fluid.

Referring to FIGS. 1-5, FIG. 5 further illustrates the server node connection rod 500, according to an example of the present disclosure. The server node connection rod 500 may be fixedly disposed in the aperture 318 of the heat sink 300. The server node connection rod 500 may include concentric passages 502, 504 therein for respectively receiving the cooling fluid for the heat sink 300 and removing the cooling fluid from the heat sink 300. Alternatively, the configurations of the passages 502, 504 may be reversed such that the passage 504 receives the cooling fluid for the heat sink 300 and the passage 502 is used to remove the cooling fluid from the heat sink 300. The server node connection rod 500 may also include a passage provided therein or on the outer walls thereof, or may be otherwise directly used for providing power to the sever node 100 via the power connectors 306 of the head module 112. Although the server node connection rod 500 is illustrated as including a circular cross-section, the server node connection rod 500 may alternatively include an oval, or otherwise non-circular cross-section to facilitate predetermined orientation of the sever node 100 when connected, for example, in the cluster configuration of FIG. 7. Further, the server node connection rod 500 may also include locating pins (e.g., a protrusion on the server node connection rod 500, or a protrusion in the aperture 318) for facilitating predetermined orientation of the sever node 100.

Referring to FIGS. 1-6, FIG. 6 illustrates another isometric view of the server node 100 in a folded configuration, and an auxiliary device such as the adapter 600 used with the server node 100, according to an example of the present disclosure. The adapter 600 may be any type of external adapter that may be used to connect external devices, for example, via Ethernet ports 602, to optical (or electrical) I/O receivers and transmitters 604 of the server node 100. For example, the adapter 600 may provide interfaces such as networking, peripheral component interconnect (PCI) express, etc.

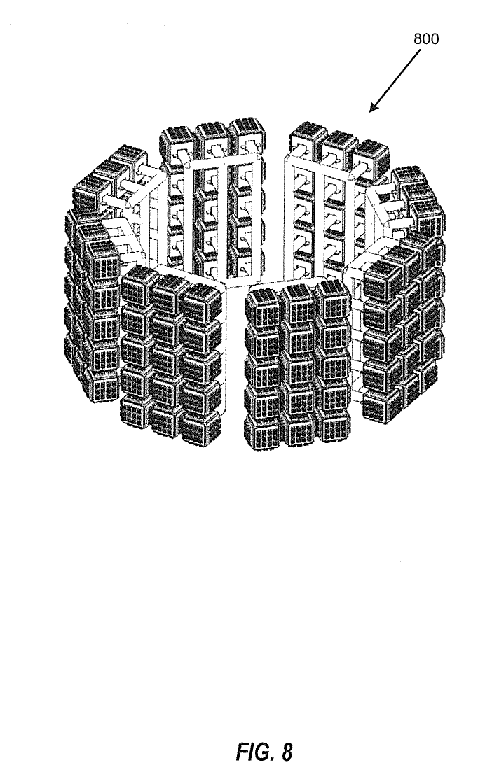

Referring to FIGS. 1-7, FIG. 7 illustrates an isometric view of a cluster 700 of server nodes 100, according to an example of the present disclosure. The cluster 700 may include a plurality of the server nodes 100 disposed in a stacked arrangement to provide a peer-to-peer mesh. The peer-to-peer mesh may include a variety of configurations, such as two-dimensional (2D) mesh configurations, wrapped around in one dimension configurations (e.g., covering the surface of a cylinder as shown in FIG. 8), and wrapped around in two dimensions (e.g., covering the surface of a torus as shown in FIG. 7). The server nodes 100 may be connected by node inter-connectors 702 that receive and connect the server node connection rods 500 of different server nodes 100. The node inter-connectors 702 may include passages that correspond to passages 502 and 504 of the server node connection rod 500 for passage and removal, respectively, of the cooling fluid for the heat sink 300. As shown in FIG. 7, certain server nodes may be connected such that centrally disposed server nodes (e.g., server node 704) include an adjacently disposed node connected to each of the face modules 104, 106, 108, and 110 of the centrally disposed server node. For server nodes, such as the server node 706 that includes exposed I/O receivers and transmitters 302, 304, optical fibers that plug into the modules or other solid medium (not shown) may be used to provide connections with other server nodes. Thus, for server nodes that include gaps, such as the server node 706, any of a variety of techniques may be used to place, cables or optical fibers to bridge such server nodes. For example, for server nodes that include gaps, other techniques for connecting such server nodes may include using a set of optical fibers that are held in a frame that orients endpoints of the optical fibers for alignment with the transmitters and receivers on the modules. According to another example, a set of optical fibers may be embedded in a solid medium that orients endpoints of the optical fibers for alignment with the transmitters and receivers on the modules. The solid medium may include box-shaped structures for the torus configuration of FIG. 7, or wedge-shaped structures for the cylindrical configuration of FIG. 8.

Referring to FIGS. 6 and 7, the I/O receivers and transmitters 604 of the server nodes may be exposed for connection to adapters, such as, the adapter 600. A cooling conduit (not shown) may be disposed in a vertical orientation in the configuration of FIG. 7 centrally to the walls 708, 710, 712, and 714 of the cluster 700. The cooling conduit may include a plurality of connectors that connect to the server node connection rods 500 to provide cooling fluid to the heat sinks 300 of the server nodes 100. The arrangement of the cluster 700 of FIG. 7 may also provide access to inner server nodes, such as server node 716, for example, for removal, maintenance, replacement, and attachment of adapters without the need to detach other server nodes.

The server nodes 100 may be used to form a variety of server node configurations, such as, planar, circular, torus, etc. For example, the server nodes 100 may be disposed against a planar surface to form a planar clustered configuration (e.g., one of the planar surfaces of the cluster 700). Further, the server nodes 100 may be disposed around a cylindrical surface to form a cylindrical clustered configuration. For example, Referring to FIGS. 1-8, FIG. 8 illustrates an isometric view of a cluster 800 of server nodes in a cylindrical configuration, according to an example of the present disclosure cluster. For the cylindrical clustered configuration, all server nodes except those at the edges of the cylinder may include an adjacently disposed node connected to each of the face modules 104, 106, 108, and 110 of centrally disposed server nodes.

In addition to the foregoing examples of FIGS. 7 and 8 of the server nodes being members of a peer-to-peer mesh, other types of nodes may also be members of the peer-to-peer mesh. For example, I/O interfaces of various types such as the adapter 600, specialized storage nodes, or coprocessors, may also be members of the peer-to-peer mesh.

Various components of devices that may use and operate the server node 100 may comprise machine readable instructions stored on a non-transitory computer readable medium. In addition, or alternatively, various components of devices that may use and operate the server node 100, may comprise hardware or a combination of machine readable instructions and hardware.

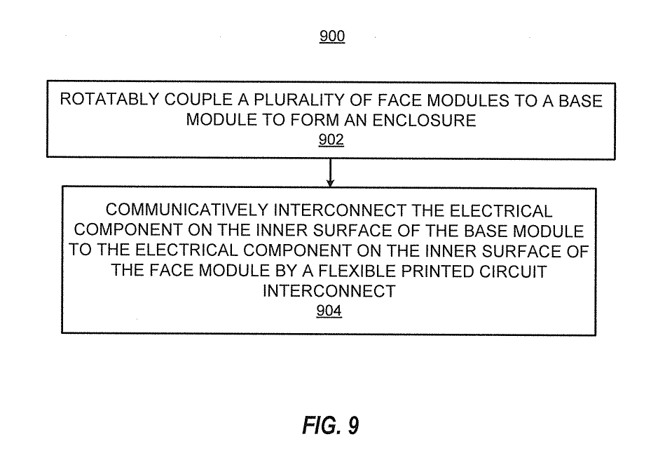

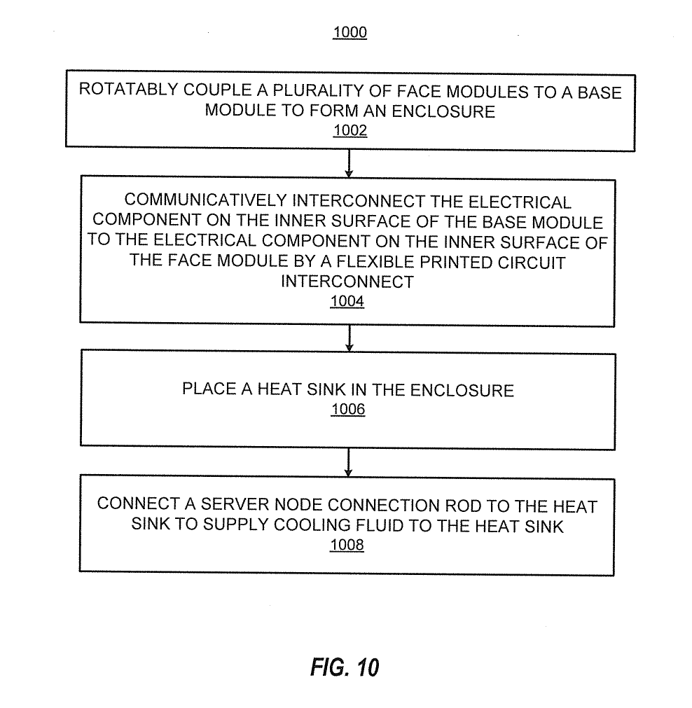

FIGS. 9 and 10 respectively illustrate flowcharts of methods 900 and 1000 for assembly of a server node, corresponding to the example of the server node 100 whose construction is described in detail above. The methods 900 and 1000 may be implemented on the server node 100 with reference to FIGS. 1-6 by way of example and not limitation. The methods 900 and 1000 may be practiced in other apparatus.

Referring to FIG. 9, for the method 900, at block 902, a plurality of face modules may be rotatably coupled to a base module to form an enclosure. The base module and a face module of the plurality of face modules may each include an inner surface that includes an electrical component. Further, an outer surface of one of the plurality of face modules may include I/O receivers and transmitters to communicate with further server nodes. For example, referring to FIG. 1, the face modules 104, 106, 108, and 110 may be rotatably coupled to the base module 102 to form an enclosure. The base module 102 and a face module (e.g., one of the face modules 104, 106, 108, and 110) of the plurality of face modules may each include an inner surface that includes an electrical component (e.g., the SOC 128, the memory 136, the power delivery circuitry 138, etc.). Further, an outer surface of one of the plurality of face modules may include I/O receivers and transmitters (e.g., the I/O receivers and transmitters 302, 304) to communicate with further server nodes.

At block 904, the electrical component on the inner surface of the base module may be communicatively interconnected to the electrical component on the inner surface of the face module by a flexible printed circuit interconnect. For example, referring to FIG. 1, the electrical component (e.g., the SOC 128) on the inner surface of the base module 102 may be communicatively interconnected to the electrical component (e.g., the memory 136) on the inner surface of the face module (e.g., the face module 108) by a flexible printed circuit interconnect (e.g., the flexible printed circuit interconnect 114).

Referring to FIG. 10, for the method 1000, at block 1002, a plurality of face modules may be rotatably coupled to a base module to form an enclosure. The base module and a face module of the plurality of face modules may each include an inner surface that includes an electrical component. Further, an outer surface of one of the plurality of face modules may include I/O receivers and transmitters to communicate with further server nodes.

At block 1004, the electrical component on the inner surface of the base module may be communicatively interconnected to the electrical component on the inner surface of the face module by a flexible printed circuit interconnect.

At block 1006, a heat sink may be placed in the enclosure. For example, referring to FIG. 3, the heat sink 300 may be placed in the enclosure.

At block 1008, a server node connection rod may be connected to the heat sink to supply cooling fluid to the heat sink. For example, referring to FIG. 5, the server node connection rod 500 may be connected to the heat sink 300 to supply cooling fluid to the heat sink.

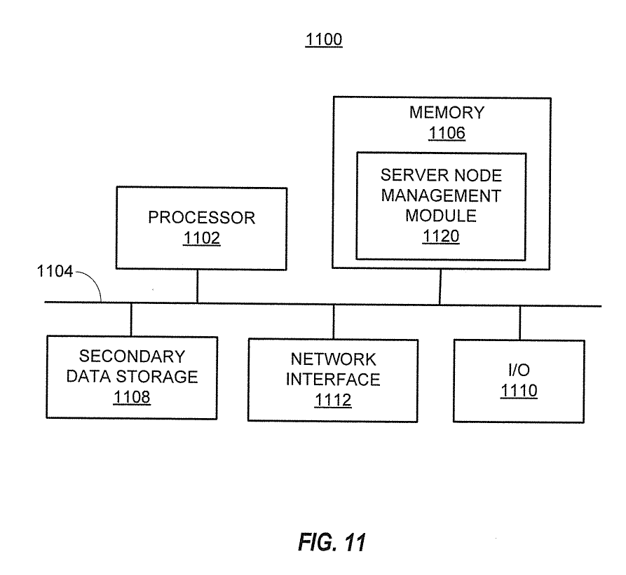

FIG. 11 shows a computer system 1100 that may be used with the examples described herein. The computer system represents a generic platform that includes components that may be in a server or another computer system. The computer system 1100 may be used as a platform for the server node 100, and/or the devices that may use and operate the server node 100. The computer system 1100 may execute, by a processor or other hardware processing circuit, the methods, functions and other processes described herein. These methods, functions and other processes may be embodied as machine readable instructions stored on a computer readable medium, which may be non-transitory, such as hardware storage devices (e.g., RAM (random access memory), ROM (read only memory), EPROM (erasable, programmable ROM), EEPROM (electrically erasable, programmable ROM), hard drives, and flash memory).

The computer system 1100 includes a processor 1102 that may implement or execute machine readable instructions performing some or all of the methods, functions and other processes described herein. Commands and data from the processor 1102 are communicated over a communication bus 1104. The computer system also includes a main memory 1106, such as a random access memory (RAM), where the machine readable instructions and data for the processor 1102 may reside during runtime, and a secondary data storage 1108, which may be non-volatile and stores machine readable instructions and data. The memory and data storage are examples of computer readable mediums. The memory 1106 may include a server node management module 1120 including machine readable instructions residing in the memory 1106 during runtime and executed by the processor 1102. The server node management module 1120 may include various components of devices that may use and manage operation of the server node 100.

The computer system 1100 may include an I/O device 1110, such as a keyboard, a mouse, a display, etc. The computer system may include a network interface 1112 for connecting to a network. Other known electronic components may be added or substituted in the computer system.

What has been described and illustrated herein is an example along with some of its variations. The terms, descriptions and figures used herein are set forth by way of illustration only and are not meant as limitations. Many variations are possible within the spirit and scope of the subject matter, which is intended to be defined by the following claims—and their equivalents—in which all terms are meant in their broadest reasonable sense unless otherwise indicated.

What is claimed is:

1. A server node comprising:
a base module;
a plurality of face modules rotatably coupled to the base module to form an enclosure when the plurality of face modules are rotated with respect to the base module, wherein the base module and a face module of the plurality of face modules each include an inner surface that includes an electrical component; and
a flexible printed circuit interconnect communicatively interconnecting the electrical component on the inner surface of the base module to the electrical component on the inner surface of the face module.

2. The server node according to claim 1, further comprising a head module rotatably coupled to one of the plurality of face modules to enclose the electrical components on the inner surface of the base module and on the inner surface of the face module.

3. The server node according to claim 1, wherein the electrical component of the base module includes a system on chip (SOC).

4. The server node according to claim 1, wherein an outer surface of one of the plurality of face modules includes input/output (I/O) receivers and transmitters to communicate with further server nodes.

5. The server node according to claim 1, wherein outer surfaces of each of the plurality of face modules include input/output (I/O) receivers and transmitters to communicate with further server nodes.

6. The server node according to claim 1, wherein an outer surface of the base module includes input/output (I/O) receivers and transmitters to communicate with auxiliary devices.

7. The server node according to claim 1, wherein the server node is attachable to other server nodes to form a cylindrical structure that includes intermediate server nodes, and wherein the intermediate server nodes include the plurality of face modules that include input/output (I/O) receivers and transmitters to communicate with each adjacently disposed server node.

8. The server node according to claim 1, wherein the server node is attachable to other server nodes to form a torus structure, and wherein a plurality of the server nodes of the torus structure include the plurality of face modules that include input/output (I/O) receivers and transmitters to communicate with each adjacently disposed server node.

9. The server node according to claim 1, further comprising a heat sink disposed in the enclosure.

10. The server node according to claim 9, further comprising a server node connection rod connected to the heat sink to supply cooling fluid to the heat sink.

11. The server node according to claim 10, wherein the server node connection rod includes concentric passages to supply the cooling fluid to the heat sink and to receive used cooling fluid from the heat sink.

12. A server node cluster comprising:
a plurality of server nodes each including:
a base module;
a plurality of face modules rotatably coupled to the base module to form an enclosure, wherein the base module and a face module of the plurality of face modules each include an inner surface that includes an electrical component; and
a flexible printed circuit interconnect communicatively interconnecting the electrical component on the inner surface of the base module to the electrical component on the inner surface of the face module,
wherein each server node of the plurality of server nodes is attachable to adjacently disposed server nodes to form a multi-dimensional structure.

13. A method for assembling a server node, the method comprising:
rotatably coupling a plurality of face modules to a base module to form an enclosure, wherein the base module and a face module of the plurality of face modules each include an inner surface that includes an electrical component, and wherein an outer surface of one of the plurality of face modules includes input/output (I/O) receivers and transmitters to communicate with further server nodes; and
communicatively interconnecting the electrical component on the inner surface of the base module to the electrical component on the inner surface of the face module by a flexible printed circuit interconnect.

14. The method of claim 13, further comprising:
placing a heat sink in the enclosure.

15. The method of claim 14, further comprising:
connecting a server node connection rod to the heat sink to supply cooling fluid to the heat sink.
